(19) United States
(12) Patent Application Publication
(10) Pub. No.: US 2023/0146758 A1
(43) Pub. Date: May 11, 2023

(54) SEMICONDUCTOR DEVICE

(71) Applicant: ROHM CO., LTD., Kyoto-shi, Kyoto (JP)

(72) Inventor: Tatsuya MIYAZAKI, Kyoto-shi, Kyoto (JP)

(21) Appl. No.: 17/914,713

(22) PCT Filed: Mar. 17, 2021
(86) PCT No.: PCT/JP2021/010866

§ 371 Date: Sep. 26, 2022

(30) Foreign Application Priority Data
Mar. 30, 2020 (JP) 2020-060295

(51) Int. Cl. H01L 23/498; H01L 25/16; H01L 23/00; H01L 23/495

(52) U.S. Cl. CPC H01L 23/49811; H01L 25/16; H01L 24/40; H01L 23/495; H01L 24/48; H01L 2224/48227; H01L 24/73; H01L 2224/73221; H01L 2224/40227; H01L 23/5386

(57) ABSTRACT

A semiconductor device includes at least one semiconductor element having a switching function; a conductive member that forms a path of a current switched by the semiconductor element, and that is made of a first material; and a covering layer that covers at least a portion of the conductive member, and that is made of a second material. The second material satisfies at least one of the following three requirements: (a) having a magnetic permeability higher than the first material; (b) having an electrical resistivity higher than the first material; and (c) having a dielectric loss tangent larger than zero.

### TECHNICAL FIELD

The present disclosure relates to a semiconductor device including a semiconductor element.

### BACKGROUND ART

Patent document 1 discloses a conventional semiconductor device. The semiconductor device described in Patent document 1 includes a semiconductor element, an island, a lead, a plurality of bonding members, a connecting plate, and a sealing resin. The semiconductor element in the semiconductor device is a transistor such as a metal-oxide-semiconductor field-effect transistor (MOSFET).

### PRIOR ART DOCUMENT

### Patent Document

Patent Document 1: JP-A-2011-204863

### SUMMARY OF THE INVENTION

### Problem to be Solved by the Invention

When the semiconductor device is energized, a main circuit current switched by the semiconductor element flows through a path formed by the island and the lead. As the switching speed increases, ringing is more likely to occur in the main circuit current, and the ringing may cause electromagnetic interference noise that may adversely affect the operation of a peripheral device.

In view of the foregoing problem, an object of the present disclosure is to provide a semiconductor device capable of suppressing ringing.

### Means to Solve the Problem

A semiconductor device provided by the present disclosure includes: at least one semiconductor element having a switching function; a conductive member that forms a path of a current switched by the semiconductor element, and that is made of a first material; and a covering layer that covers at least a portion of the conductive member, and that is made of a second material. The second material satisfies at least one of the following three requirements: (a) having a magnetic permeability higher than the first material; (b) having an electrical resistivity higher than the first material; and (c) having a dielectric loss tangent larger than zero.

Preferably, the second material is a magnetic conductor having a magnetic permeability higher than the first material and having an electrical resistivity higher than the first material.

Preferably, the second material has a dielectric loss tangent larger than zero.

Preferably, the second material has a magnetic permeability higher than the first material, and has a dielectric loss tangent larger than zero.

Preferably, the second material has an electrical resistivity higher than the first material, and has a dielectric loss tangent larger than zero.

Preferably, the covering layer has a thickness of 1 μm to 5 μm.

Preferably, a relative magnetic permeability of the second material is not less than 10.

Preferably, the electrical resistivity of the second material is not less than twice the electrical resistivity of the first material.

Preferably, the dielectric loss tangent of the second material is not less than 0.01.

Preferably, the semiconductor device according to the present disclosure further includes a capacitor having a first end and a second end for electrical connection. The at least one semiconductor element includes a plurality of semiconductor elements that form a half-bridge including at least a pair of upper arm and lower arm, where the plurality of semiconductor elements include a first semiconductor element in the upper arm and a second semiconductor element in the lower arm. The conductive member includes a first metal layer connected to a drain electrode of the first semiconductor element, a first power lead connected to the first metal layer, and a second power lead connected to a source electrode of the second semiconductor element. The first end of the capacitor is connected to the first power lead, and the second end of the capacitor is connected to the second power lead. The covering layer includes a first portion covering the first power lead and a second portion covering the second power lead.

Preferably, the first power lead includes a portion forming a path between the first semiconductor element and the capacitor, and the portion of the first power lead is not covered with the first portion.

Preferably, the second power lead includes a portion forming a path between the second semiconductor element and the capacitor, and the portion of the second power lead is not covered with the second portion.

Preferably, the covering layer includes a third portion covering the first metal layer.

Preferably, the conductive member includes a second metal layer connected to a drain electrode of the second semiconductor element, and a third power lead connected to the second metal layer, and the second metal layer and the third power lead are not covered with the covering layer.

Preferably, the conductive member includes an intermediate lead connected to a source electrode of the first semiconductor element and the second metal layer, and the intermediate lead is not covered with the covering layer.

Preferably, the conductive member includes a first spacer interposed between the first metal layer and the first power lead, and the covering layer includes a fourth portion covering the first spacer.

Preferably, the conductive member includes a conductor interposed between the source electrode of the second semiconductor element and the second power lead.

Preferably, the semiconductor element is one of a SiC MOSET, a SiC IGBT, a Si MOSFET, a Si IGBT, and a GaN HEMT.

### Advantages of the Invention

The semiconductor device according to the present disclosure can suppress ringing, simplify a snubber circuit, and improve reliability.

### BRIEF DESCRIPTION OF THE DRAWINGS

FIG. 1 is a perspective view showing a semiconductor device according to a first embodiment.

FIG. 2 is a perspective view showing main parts of the semiconductor device according to the first embodiment.

FIG. 3 is a plan view showing the semiconductor device according to the first embodiment.

FIG. 4 is a plan view corresponding to FIG. 3, with a sealing resin indicated by an imaginary line.

FIG. 5 is a partially enlarged plan view showing a part of

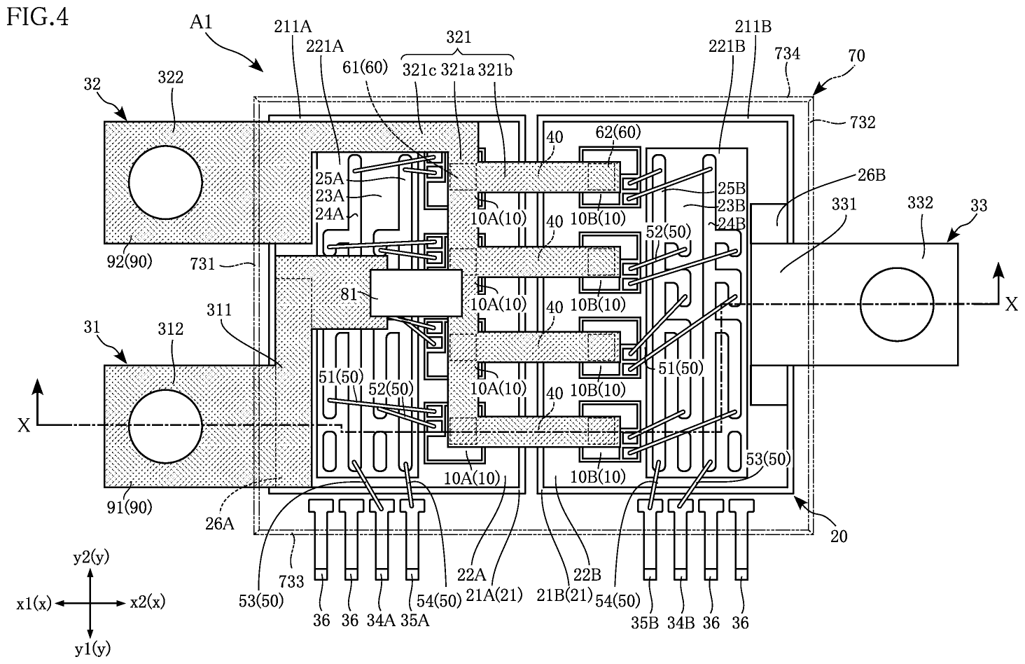

FIG. 4.

FIG. 6 is a front view showing the semiconductor device according to the first embodiment.

FIG. 7 is a bottom view showing the semiconductor device according to the first embodiment.

FIG. 8 is a left side view showing the semiconductor device according to the first embodiment.

FIG. 9 is a right side view showing the semiconductor device according to the first embodiment.

FIG. 10 is a cross-sectional view along line X-X in FIG. 4.

FIG. 11 is a cross-sectional view along line XI-XI in FIG. 10.

FIG. 12 is a cross-sectional view showing a first variation of the semiconductor device according to the first embodiment.

FIG. 13 is a cross-sectional view showing a second variation of the semiconductor device according to the first embodiment.

FIG. 14 is a perspective view showing main parts of a semiconductor device according to a second embodiment.

FIG. 15 is a plan view showing the semiconductor device according to the second embodiment.

FIG. 16 is a cross-sectional view along line XVI-XVI in FIG. 15.

FIG. 17 is a perspective view showing main parts of a semiconductor device according to a third embodiment.

FIG. 18 is a plan view showing the semiconductor device according to the third embodiment.

FIG. 19 is a cross-sectional view along line XIX-XIX in FIG. 18.

FIG. 20 is a plan view showing a semiconductor device according to a fourth embodiment.

FIG. 21 is a cross-sectional view along line XXI-XXI in FIG. 20.

### MODE FOR CARRYING OUT THE INVENTION

Preferred embodiments of a semiconductor device according to the present disclosure are described below with reference to the drawings.

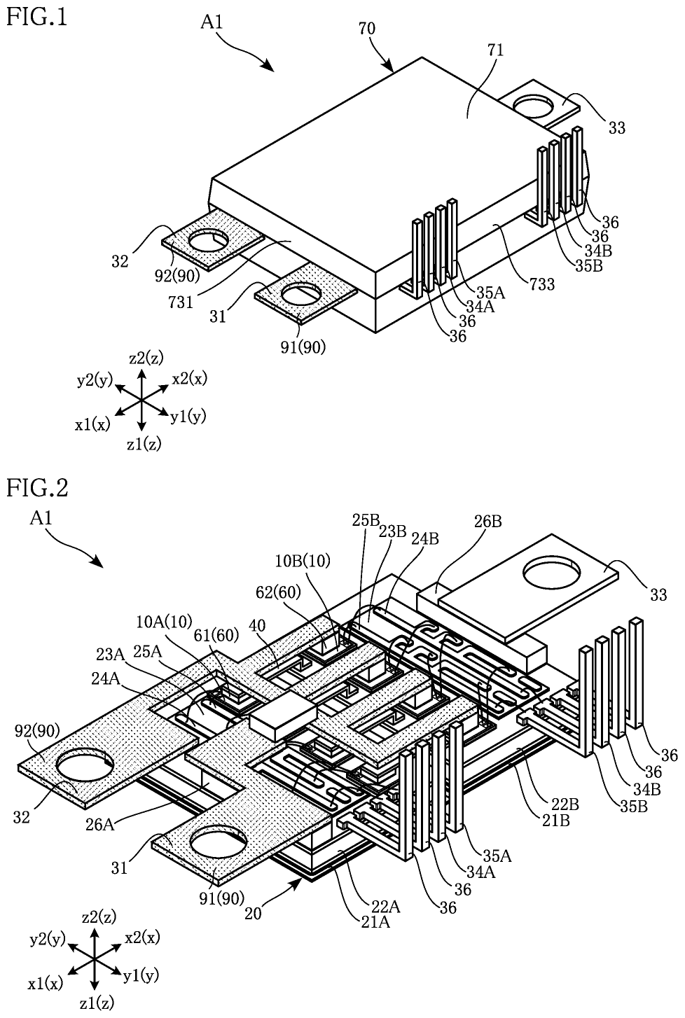

FIGS. 1 to 11 show a semiconductor device according to a first embodiment. A semiconductor device A1 according to the first embodiment includes a plurality of semiconductor elements 10, a support substrate 20, a plurality of leads, a plurality of intermediate leads 40, a plurality of wire members 50, a plurality of conductive blocks 60, a sealing resin 70, a capacitor 81, and a covering layer 90. The plurality of leads include a first power lead 31, a second power lead 32, a third power lead 33, a pair of gate leads 34A and 34B, a pair of driver source leads 35A and 35B, and a plurality of dummy leads 36. The conductive blocks 60 include a plurality of first blocks 61 and a plurality of second blocks 62.

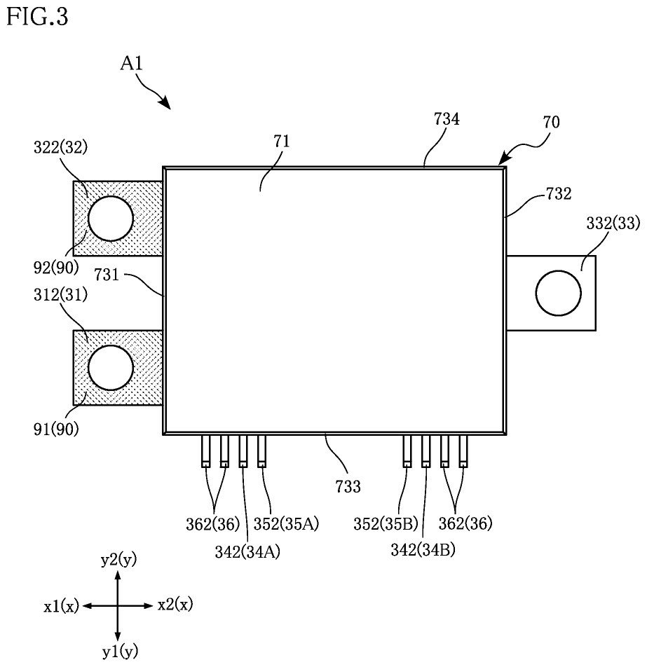

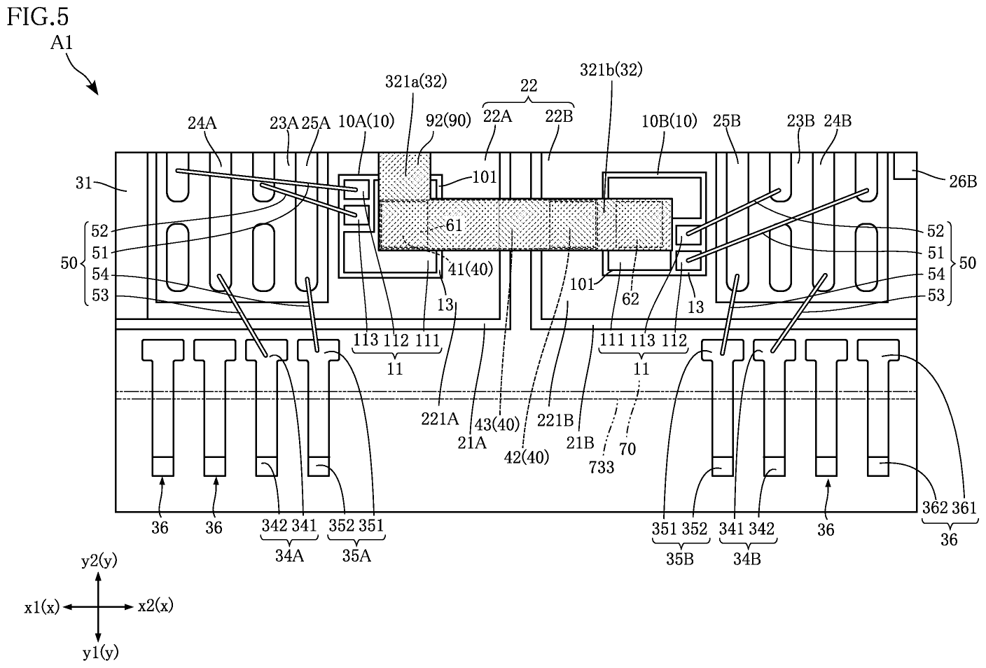

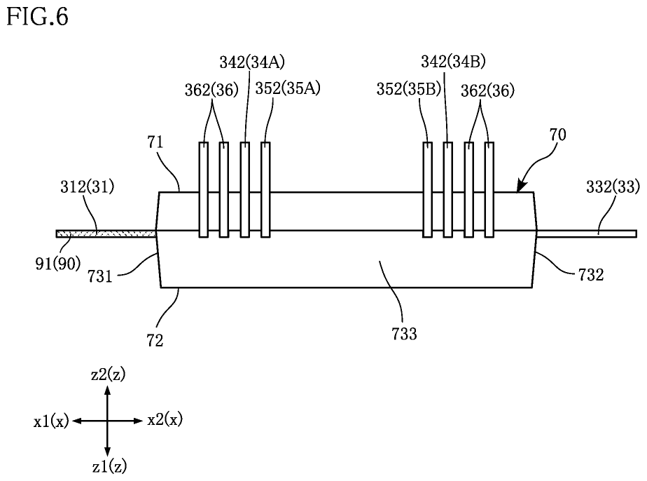

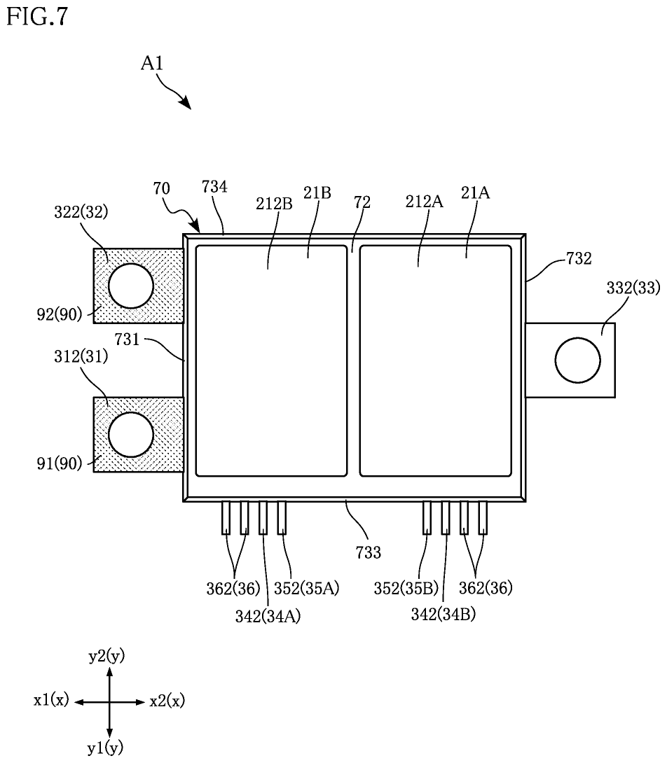

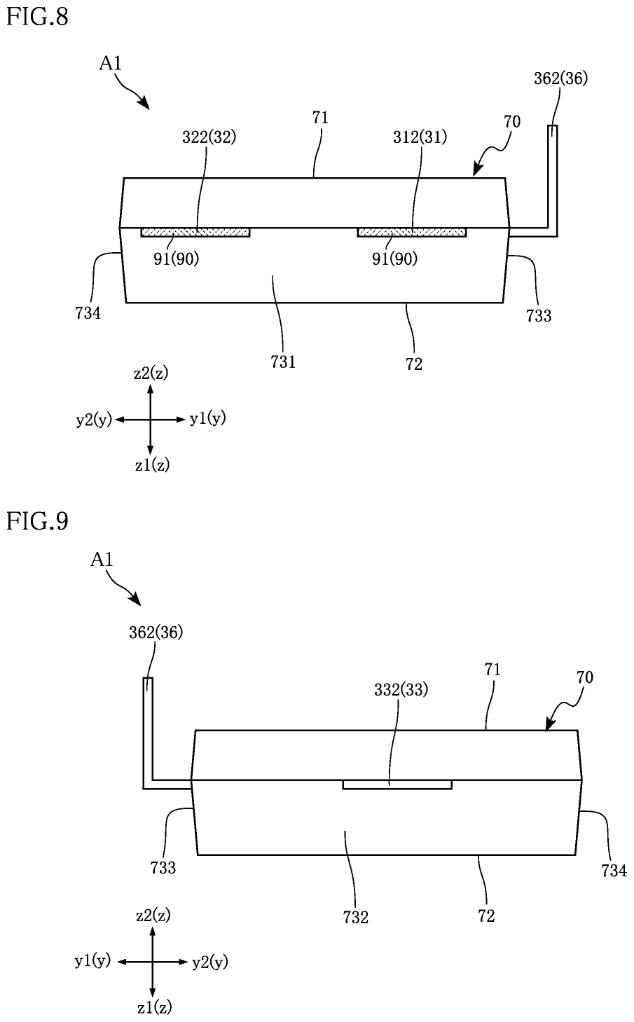

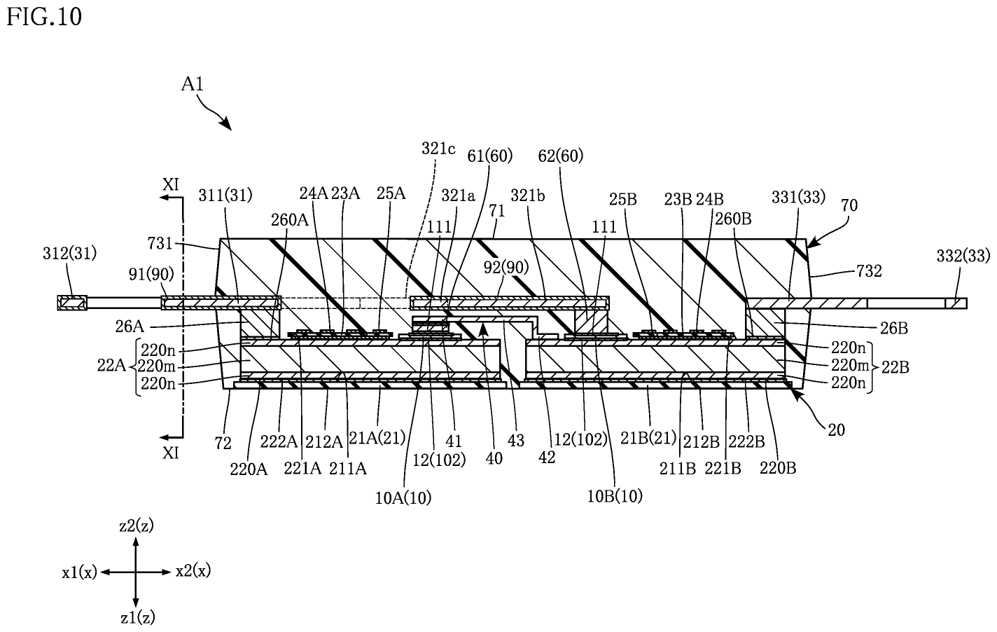

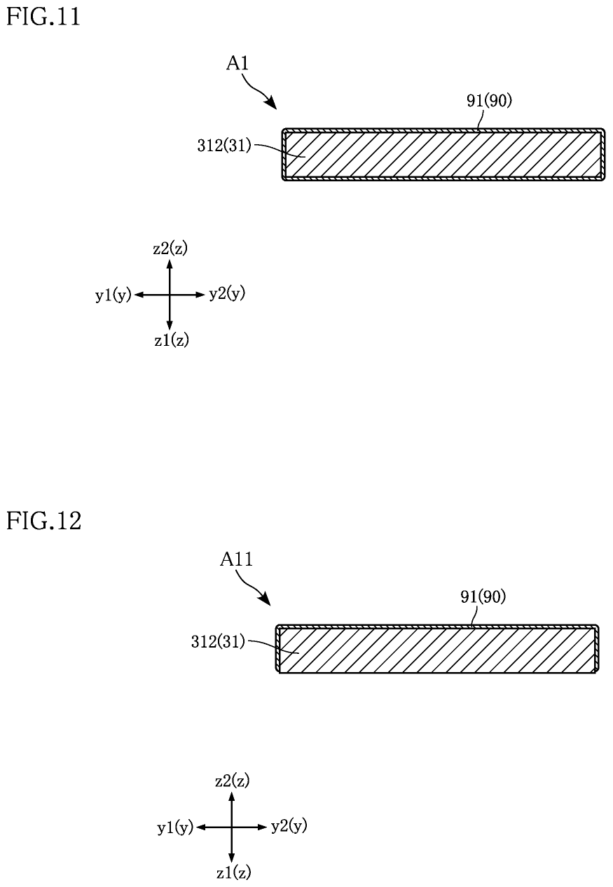

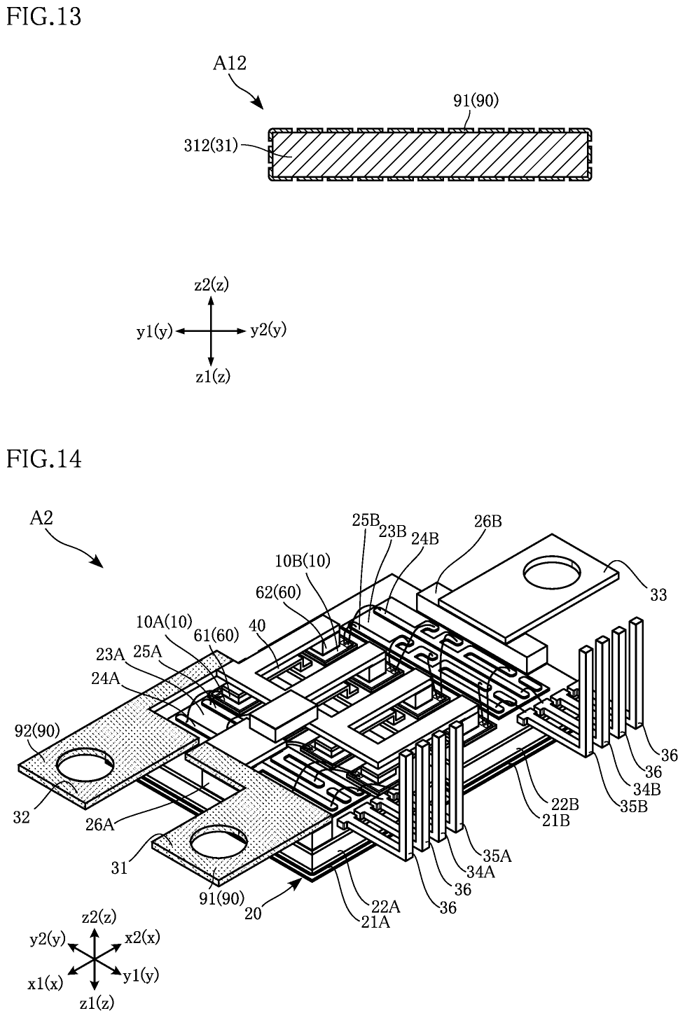

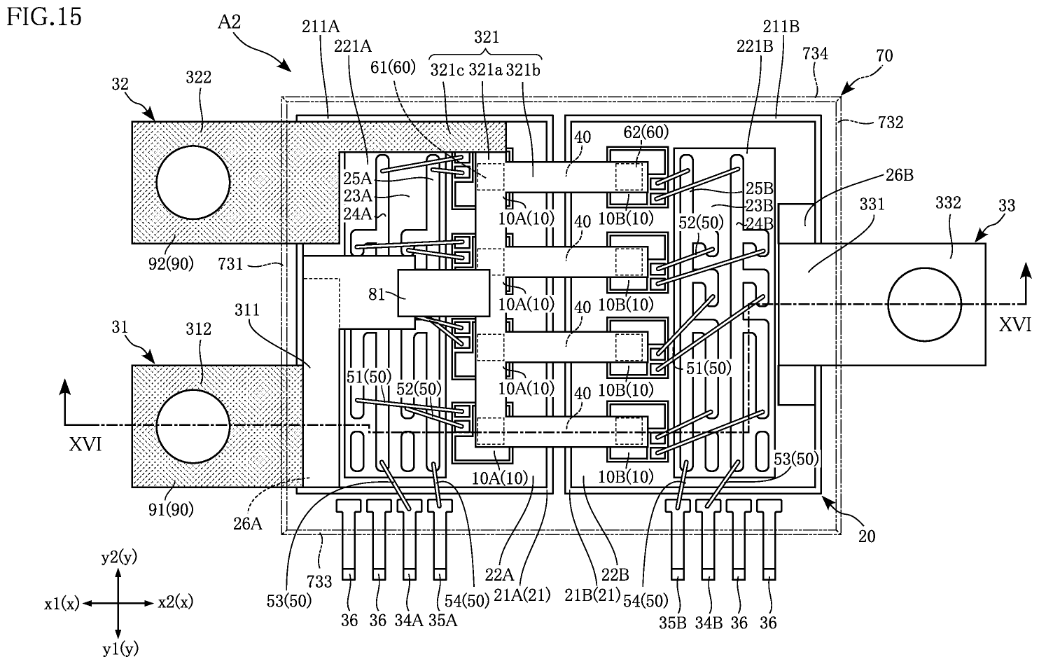

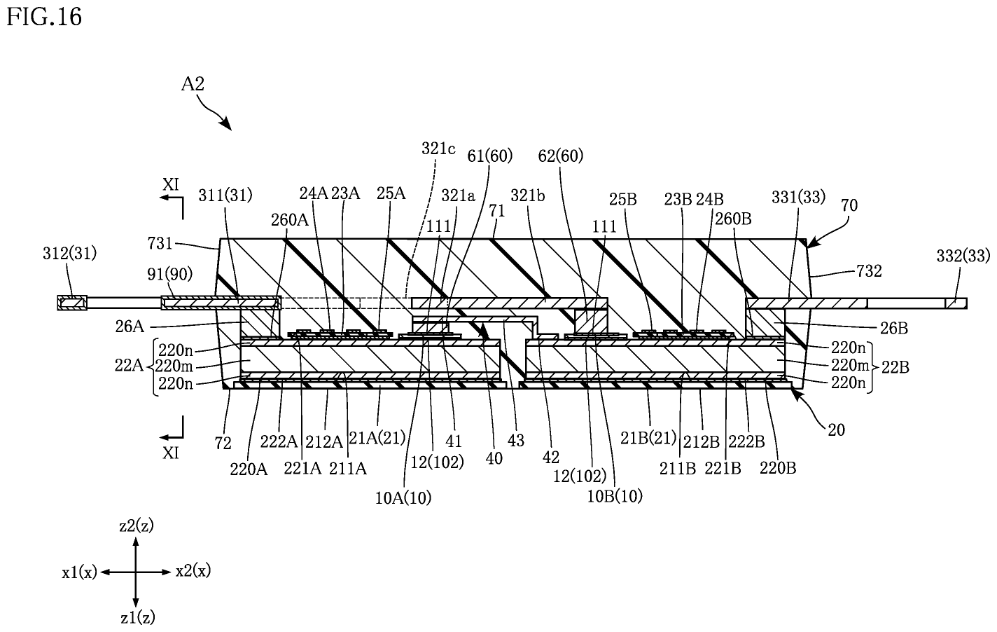

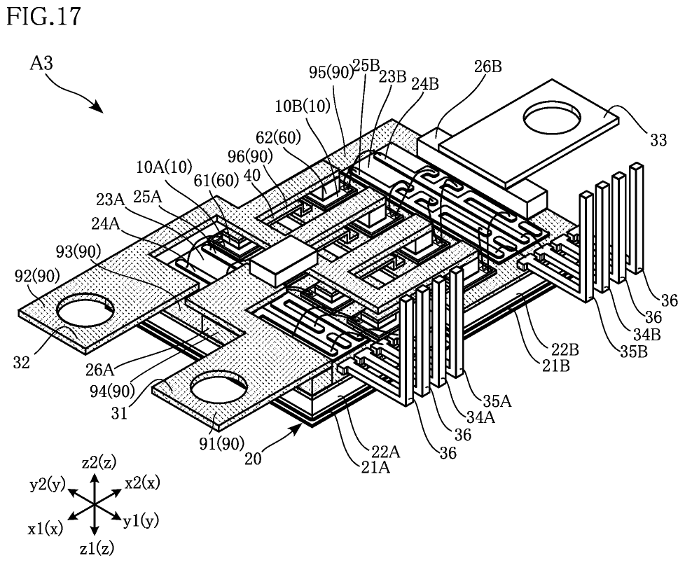

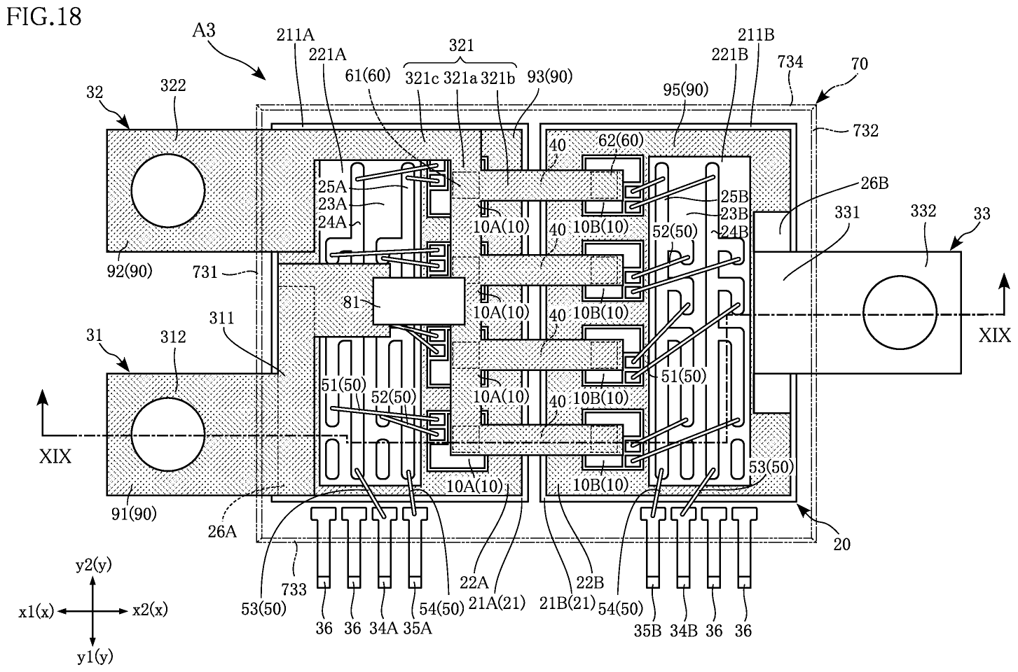

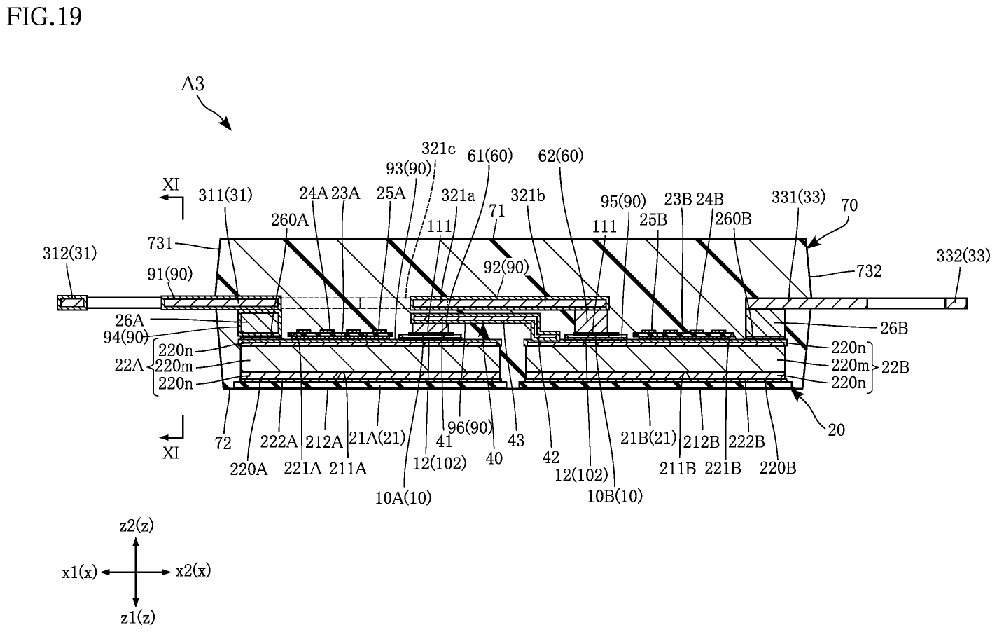

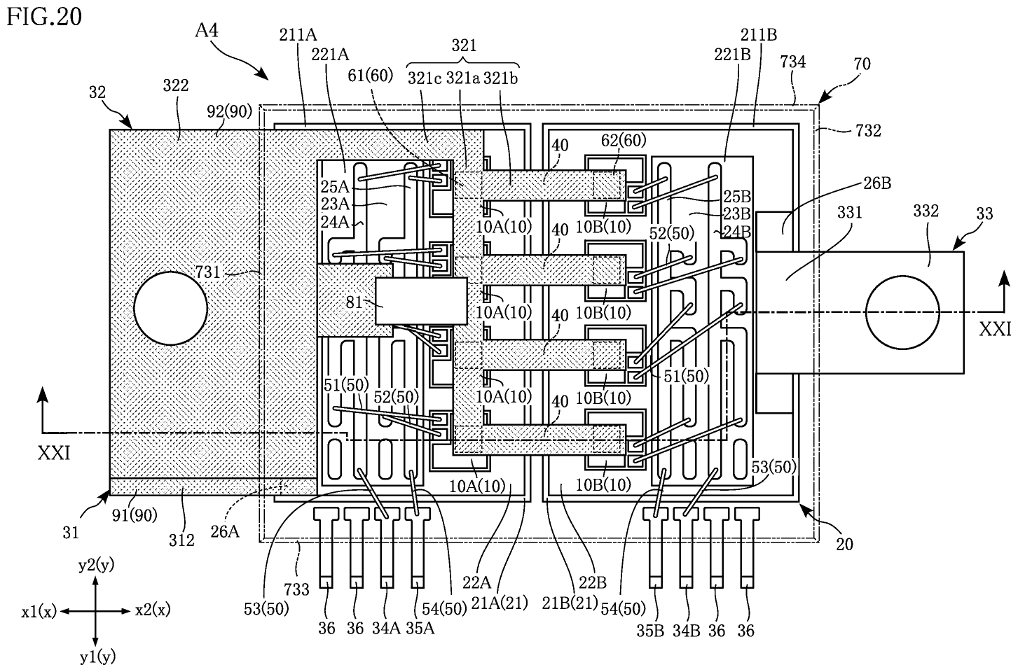

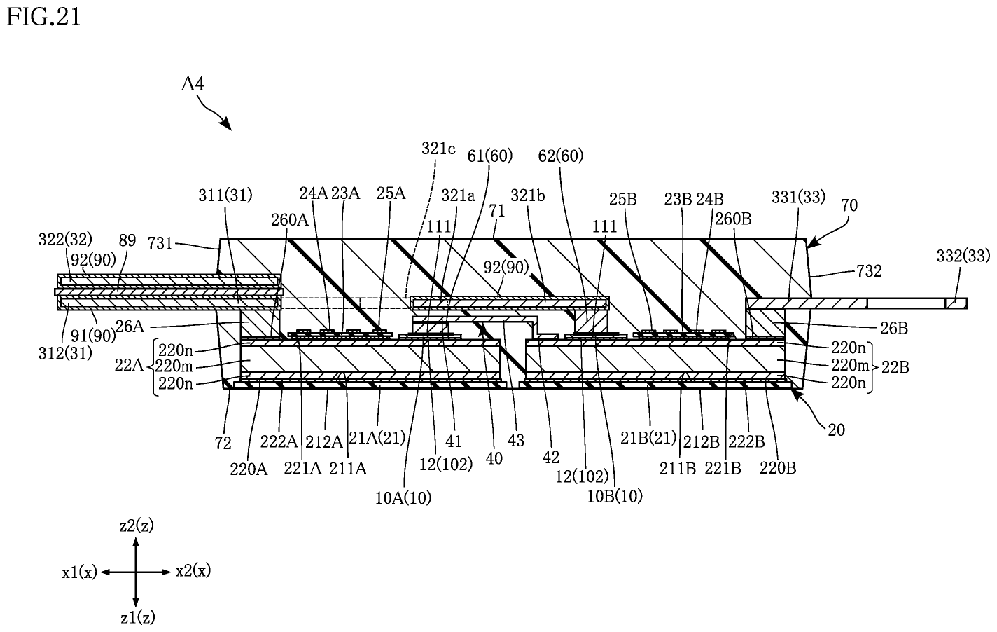

FIG. 1 is a perspective view showing the semiconductor device A1. FIG. 2 is a perspective view corresponding to FIG. 1 but omitting the sealing resin 70. The wire members 50 are omitted in FIG. 2. FIG. 3 is a plan view showing the semiconductor device A1. FIG. 4 is a plan view corresponding to FIG. 3, with the sealing resin 70 indicated by an imaginary line (two-dot chain line). FIG. 5 is a partially enlarged view showing a part of FIG. 4. FIG. 6 is a front view showing the semiconductor device A1. FIG. 7 is a bottom view showing the semiconductor device A1. FIG. 8 is a left side view showing the semiconductor device A1. FIG. 9 is a right side view showing the semiconductor device A1. FIG. 10 is a cross-sectional view along line X-X in FIG. 4. FIG. 11 is a cross-sectional view along line XI-XI in FIG. 10. In FIGS. 1 to 8, a plurality of dots are depicted in the covering layer 90 to facilitate understanding.

In the following description, three mutually perpendicular directions (x direction, y direction, and z direction) will be referred to as appropriate. The z direction corresponds to the thickness direction of the semiconductor device A1. The x direction corresponds to the horizontal direction in the plan views (see FIGS. 3 and 4) of the semiconductor device A1. The y direction corresponds to the vertical direction in the plan views (see FIGS. 3 and 4) of the semiconductor device A1. As need arises, one sense of the x direction is defined as x1 direction, and the other sense as x2 direction. Similarly, one sense of the y direction is defined as y1 direction, and the other sense as y2 direction. One sense of the z direction is defined as z1 direction, and the other sense as z2 direction.

Each of the semiconductor elements 10 has a function of switching the main circuit current, and is not limited to any specific configuration. Specifically, the semiconductor elements 10 may be silicon carbide (SiC) MOSETs, SiC insulated gate bipolar transistors (IGBTs), Si MOSFETs, Si IGBTs, and gallium nitride (GaN) high electron mobility transistors (HEMTs). Each of the semiconductor elements 10 has a rectangular shape as viewed in the z direction (also referred to as “plan view”), but the present disclosure is not limited to this.

As shown in FIGS. 5 and 10, each of the semiconductor elements 10 has an element obverse surface 101 and an element reverse surface 102. In each of the semiconductor elements 10, the element obverse surface 101 and the element reverse surface 102 are spaced apart and face away from each other in the z direction. In the present embodiment, the element obverse surface 101 faces in the z2 direction, and the element reverse surface 102 faces in the z1 direction.

As shown in FIGS. 5 and 10, each of the semiconductor elements 10 has an obverse surface electrode 11, a reverse surface electrode 12, and an insulating film 13.

As shown in FIG. 5, the obverse surface electrode 11 is provided on the element obverse surface 101. As shown in FIG. 5, the obverse surface electrode 11 includes a source electrode 111, a gate electrode 112, and a driver source electrode 113. In the present embodiment, the source electrode 111 is an electrode through which a source current flows. In the present embodiment, the gate electrode 112 is an electrode to which a gate voltage for driving the semiconductor element 10 is applied. The driver source electrode 113 provides a reference potential for the gate voltage. The source electrode 111 is larger than each of the gate electrode 112 and the driver source electrode 113. The gate electrode 112 and the driver source electrode 113 have substantially the same size. In the present embodiment, the source electrode 111 includes a single region. However, the source electrode 111 may be divided into multiple regions.

As shown in FIG. 10, the reverse surface electrode 12 is provided on the element reverse surface 102. The reverse surface electrode 12 is formed over the entirety of the element reverse surface 102. In the present embodiment, the reverse surface electrode 12 is an electrode through which a drain current flows. In the following description, the reverse surface electrode 12 is also referred to as a drain electrode 12.

As shown in FIG. 5, the insulating film 13 is provided on the element obverse surface 101. The insulating film 13 is electrically insulative. The insulating film 13 surrounds the obverse surface electrode 11 in plan view. The insulating film 13 insulates the source electrode 111 and the gate electrode 112 from each other. The insulating film 13 may be formed by stacking a silicon dioxide (SiO₂) layer, a silicon nitride (Si₃N₄) layer, and a polybenzoxazole layer in this order on the element obverse surface 101, with the polybenzoxazole layer being a surface layer. The polybenzoxazole layer in the insulating film 13 may be replaced with a polyimide layer. The insulating film 13 is not limited to having the configuration described above.

The plurality of semiconductor elements 10 include a plurality of first semiconductor elements 10A and a plurality of second semiconductor elements 10B. In the present embodiment, the semiconductor device A1 is configured as a half-bridge switching circuit. The first semiconductor elements 10A constitute an upper arm circuit of the switching circuit, and the second semiconductor elements 10B constitute a lower arm circuit of the switching circuit. As shown in FIG. 4, the semiconductor device A1 includes four first semiconductor elements 10A and four second semiconductor elements 10B. The number of semiconductor elements 10 is not limited to the above, and may be selected appropriately according to the performance required for the semiconductor device A1.

As shown in FIGS. 2, 4, 5 and 10, the first semiconductor elements 10A are mounted on the support substrate 20 (conductive substrate 22A). In the present embodiment, the first semiconductor elements 10A are aligned and spaced apart from each other in the y direction. When the first semiconductor elements 10A are mounted on the conductive substrate 22A, the element reverse surfaces 102 face the conductive substrate 22A. The first semiconductor elements 10A are electrically bonded to the support substrate 20 (conductive substrate 22A) via, for example, element bonding members (not illustrated) that are electrically conductive. Examples of the element bonding members include solder, sintered silver, and silver paste.

FIGS. 2, 4, 5 and 10, the second semiconductor elements 10B are mounted on the support substrate 20 (conductive substrate 22B). In the present embodiment, the second semiconductor elements 10B are aligned and spaced apart from each other in the y direction. When the second semiconductor elements 10B are mounted on the conductive substrate 22B, the element reverse surfaces 102 face the conductive substrate 22B. The second semiconductor elements 10B are electrically bonded to the support substrate 20 (conductive substrate 22B) via, for example, element bonding members (not illustrated) that are electrically conductive. In the present embodiment, the first semiconductor elements 10A and the second semiconductor elements 10B overlap with each other as viewed in the x direction. Alternatively, the first semiconductor elements 10A and the second semiconductor elements 10B may not overlap with each other as viewed in the x direction.

The support substrate 20 is a support member that supports the semiconductor elements 10. The support substrate 20 includes an insulating substrate 21, two conductive substrates 22A and 22B, a pair of insulating layers 23A and 23B, a pair of gate layers 24A and 24B, a pair of driver source layers 25A and 25B, a first spacer 26A, and a second spacer 26B.

The insulating substrate 21 is a plate-like member that is electrically insulative. The insulating substrate 21 supports the two conductive substrates 22A and 22B. In the present embodiment, the insulating substrate 21 includes two insulating substrates 21A and 21B that each have a flat plate-like shape. The insulating substrate 21 is not limited to having the configuration described above, and may be a single flat plate instead of being divided into the two insulating substrates 21A and 21B. Each of the insulating substrates 21A and 21B is made of a ceramic material having excellent thermal conductivity, for example. Examples of the ceramic material include aluminum nitride (AlN), silicon nitride (SiN), and aluminum oxide (Al₂O₃).

Each of the insulating substrates 21A and 21B has a rectangular shape in plan view. The insulating substrate 21A supports the conductive substrate 22A, and the insulating substrate 21B supports the conductive substrate 22B. The insulating substrates 21A and 21B are spaced apart from each other. In the present embodiment, the insulating substrate 21A and the insulating substrate 21B are spaced apart from each other and aligned in the x direction, as shown in FIGS. 2, 4, and 10.

As shown in FIG. 10, the insulating substrate 21A has an obverse surface 211A and a reverse surface 212A. The obverse surface 211A and the reverse surface 212A are spaced apart and face away from each other in the z direction. The obverse surface 211A faces in the z2 direction, and the reverse surface 212A faces in the z1 direction. The obverse surface 211A faces the conductive substrate 22A, and the reverse surface 212A is exposed from the sealing resin 70. Unlike the illustrated example, another conductive substrate may be bonded to the reverse surface 212A of the insulating substrate 21A. In this case, the reverse surface of the conductive substrate is exposed from the sealing resin 70.

As shown in FIG. 10, the insulating substrate 21B has an obverse surface 211B and a reverse surface 212B. The obverse surface 211B and the reverse surface 212B are spaced apart and face away from each other in the z direction. The obverse surface 211B faces in the z2 direction, and the reverse surface 212B faces in the z1 direction. The obverse surface 211B faces the conductive substrate 22B, and the reverse surface 212B is exposed from the sealing resin 70. Unlike the illustrated example, another conductive substrate may be bonded to the reverse surface 212B of the insulating substrate 21B. In this case, the reverse surface of the conductive substrate is exposed from the sealing resin 70.

The conductive substrates 22A and 22B are plate-like members that are electrically conductive. As shown in FIG. 10, each of the conductive substrates 22A and 22B according to the present embodiment is a composite substrate including a graphite substrate 220m and copper films 220n formed on the respective surfaces of the graphite substrate 220m in the z direction. Each of the conductive substrates 22A and 22B is not limited to having the configuration described above, and may be made of Cu or a Cu alloy. The surfaces of the conductive substrates 22A and 22B may be covered with silver plating. The conductive substrates 22A and 22B constitute a conductive path to the semiconductor elements 10, together with the leads (the first power lead 31, the second power lead 32, the third power lead 33, the pair of gate leads 34A and 34B, the pair of driver source leads 35A and 35B, and the dummy leads 36). The conductive substrates 22A and 22B are spaced apart from each other. As shown in FIGS. 4 and 10, the conductive substrate 22A and the conductive substrate 22B are spaced apart from each other and aligned in the x direction. As shown in FIG. 4, each of the conductive substrates 22A and 22B has a rectangular shape in plan view. Each of the conductive substrates 22A and 22B has a dimension of about 1.0 to 3.5 mm in the z direction. In the present embodiment, the graphite substrate 220m has a dimension of about 0.5 to 2.5 mm in the z direction, and each of the copper films 220n has a dimension of about 0.25 to 0.5 mm in the z direction. These dimensions in the z direction are not limited to those described above. One of the copper films 220n of the conductive substrate 22A, which is located on the upper side in FIG. 10, is an example of the “first metal layer”. One of the copper films 220n of the conductive substrate 22B, which is located on the upper side in FIG. 10, is an example of the “second metal layer”. The copper film 220n of the conductive substrate 22A located on the upper side in FIG. 10 and the copper film 220n of the conductive substrate 22B located on the upper side in FIG. 10 are each an example of the “conductive member”. The material of the copper film 220n of the conductive substrate 22A located on the upper side in FIG. 10 and the material of the copper film 220n of the conductive substrate 22B located on the upper side in FIG. 10 are each an example of the “first material”.

As shown in FIG. 10, the conductive substrate 22A is bonded to the insulating substrate 21A via a substrate bonding member 220A. The substrate bonding member 220A may be a conductive bonding member such as silver paste, solder, or sintered metal, or may be an insulating bonding member. As shown in FIGS. 4 and 10, the conductive substrate 22A is offset in the x1 direction relative to the conductive substrate 22B. The conductive substrate 22A entirely overlaps with the conductive substrate 22B as viewed in the x direction.

As shown in FIG. 10, the conductive substrate 22A has an obverse surface 221A and a reverse surface 222A. The obverse surface 221A and the reverse surface 222A are spaced apart and face away from each other in the z direction. The obverse surface 221A faces in the z2 direction, and the reverse surface 222A faces in the z1 direction. The first semiconductor elements 10A are mounted on the obverse surface 221A. The insulating layer 23A is bonded to the obverse surface 221A.

As shown in FIG. 10, the conductive substrate 22B is bonded to the insulating substrate 21B via a substrate bonding member 220B. The substrate bonding member 220B may be a conductive bonding member such as silver paste, solder, or sintered metal, or may be an insulating bonding member.

As shown in FIG. 10, the insulating substrate 22B has an obverse surface 221B and a reverse surface 222B. The obverse surface 221B and the reverse surface 222B are spaced apart and face away from each other in the z direction. The obverse surface 221B faces in the z2 direction, and the reverse surface 222B faces in the z1 direction. The second semiconductor elements 10B are mounted on the obverse surface 221B. The insulating layer 23B and one end of each intermediate lead 40 are bonded to the obverse surface 221B.

The pair of insulating layers 23A and 23B are electrically insulative, and are made of glass epoxy resin or ceramic. As shown in FIG. 4, each of the pair of insulating layers 23A and 23B has a band shape extending in the y direction. As shown in FIGS. 4 and 10, the insulating layer 23A is bonded to the obverse surface 221A of the conductive substrate 22A. The insulating layer 23A is offset in the x1 direction relative to the first semiconductor elements 10A. Alternatively, the insulating layer 23A may be offset in the x2 direction relative to the first semiconductor elements 10A. As shown in FIGS. 4 and 10, the insulating layer 23B is bonded to the obverse surface 221B of the conductive substrate 22B. The insulating layer 23B is offset in the x2 direction relative to the second semiconductor elements 10B. Alternatively, the insulating layer 23B may be offset in the x1 direction relative to the second semiconductor elements 10B.

The pair of gate layers 24A and 24B are electrically conductive and made of, for example, copper or a copper alloy. As shown particularly in FIG. 4, each of the gate layers 24A and 24B includes a band-shaped portion extending in the y direction, and hook-shaped portions protruding from the band-shaped portion. The shape of each of the pair of gate layers 24A and 24B is not limited to the shape shown in FIG. 4. For example, each of the gate layers 24A and 24B may be made of only the band-shaped portion without the hook-shaped portions. As shown in FIGS. 4 and 10, the gate layer 24A is provided on the insulating layer 23A. The gate layer 24A is electrically connected to the gate electrodes 112 of the first semiconductor elements 10A via some of the wire members 50 (gate wires 51 described below). As shown in FIGS. 4 and 10, the gate layer 24B is provided on the insulating layer 23B. The gate layer 24B is electrically connected to the gate electrodes 112 of the second semiconductor elements 10B via some of the wire members 50 (gate wires 51 described below).

The pair of driver source layers 25A and 25B are electrically conductive, and may be made of Cu or a Cu alloy. As shown particularly in FIG. 4, each of the driver source layers 25A and 25B includes a band-shaped portion extending in the y direction, and hook-shaped portions protruding from the band-shaped portion. The shape of each of the pair of driver source layers 25A and 25B is not limited to the shape shown in FIG. 4. For example, each of the driver source layers 25A and 25B may be made of only the band-shaped portion without the hook-shaped portions. As shown in FIGS. 4 and 10, the driver source layer 25A is provided on the insulating layer 23A, together with the gate layer 24A. In plan view, the driver source layer 25A is adjacent to and spaced apart from the gate layer 24A on the insulating layer 23A. In the present embodiment, the driver source layer 25A is closer to the first semiconductor elements 10A than the gate layer 24A in the x direction. Accordingly, the driver source layer 25A is offset in the x2 direction relative to the gate layer 24A. Note that the positions of the gate layer 24A and the driver source layer 25A in the x direction may be switched around. The driver source layer 25A is electrically connected to the driver source electrodes 113 of the first semiconductor elements 10A via some of the wire members 50 (driver source wires 52). As shown in FIGS. 4 and 10, the driver source layer 25B is provided on the insulating layer 23B, together with the gate layer 24B. In plan view, the driver source layer 25B is adjacent to and spaced apart from the gate layer 24B on the insulating layer 23B. In the present embodiment, the driver source layer 25B is closer to the second semiconductor elements 10B than the gate layer 24B. Accordingly, the driver source layer 25B is offset in the x1 direction relative to the gate layer 24B. Note that the positions of the gate layer 24B and the driver source layer 25B in the x direction may be switched around. The driver source layer 25B is electrically connected to the driver source electrodes 113 of the second semiconductor elements 10B via some of the wire members 50 (driver source wires 52).

The first spacer 26A and the second spacer 26B are electrically conductive, and may be made of Cu or a Cu alloy. The material of each of the first spacer 26A and the second spacer 26B is not limited to the material described above, and may be a composite of Cu molybdenum (CuMo) or a composite of copper-inver-copper (CIC). The first spacer 26A and the second spacer 26B may be made of different materials. Each of the first spacer 26A and the second spacer 26B is an example of the “conductive member”, and the material of each of the first spacer 26A and the second spacer 26B is an example of the “first material”.

As shown in FIG. 10, the first spacer 26A is interposed between the conductive substrate 22A and the first power lead 31. As shown in FIG. 4, the first spacer 26A has a rectangular shape extending in the y direction in plan view. The first spacer 26A is electrically bonded to the conductive substrate 22A. The first spacer 26A is positioned near the edge of the conductive substrate 22A in the x1 direction in plan view. The first spacer 26A is provided so that the first power lead 31 is substantially at the same position as the second power lead 32 in the z direction. Alternatively, the first power lead 31 may be bonded directly to the conductive substrate 22A without the first spacer 26A. The shape of the first spacer 26A is not particularly limited.

As shown in FIG. 10, the second spacer 26B is interposed between the conductive substrate 22B and the third power lead 33. As shown in FIG. 4, the second spacer 26B has a rectangular shape extending in the y direction in plan view. The second spacer 26B is electrically bonded to the conductive substrate 22B. The second spacer 26B is positioned near the edge of the conductive substrate 22B in the x2 direction in plan view. The second spacer 26B is provided so that the third power lead 33 is substantially at the same position as the second power lead 32 in the z direction. Alternatively, the third power lead 33 may be bonded directly to the conductive substrate 22B without the second spacer 26B. The shape of the second spacer 26B is not particularly limited.

Each of the leads (the first power lead 31, the second power lead 32, the third power lead 33, the pair of gate leads 34A and 34B, the pair of driver source leads 35A and 35B, and the dummy leads 36) includes a portion inside the sealing resin 70 and a portion outside the sealing resin 70. That is, each of the leads includes a portion covered with the sealing resin 70 and a portion exposed from the sealing resin 70. The leads are used when the semiconductor device A1 is mounted on the circuit board of an electronic device or the like.

The first power lead 31 and the second power lead 32 are metal plates. Each of the metal plates is made of Cu or a Cu alloy. The material of the first power lead 31 and the second power lead 32 is not limited to Cu or a Cu alloy, and may be aluminum, for example. In the present embodiment, each of the first power lead 31 and the second power lead 32 has a dimension of about 0.8 mm in the z direction. However, the present disclosure is not limited to this. As shown in FIGS. 1 to 4 and FIG. 7, the first power lead 31 and the second power lead 32 are offset in the x1 direction in the semiconductor device A1. Source voltage is applied across the first power lead 31 and the second power lead 32, for example. The first power lead 31 is a positive terminal (P terminal), and the second power lead 32 is a negative terminal (N terminal). The first power lead 31 and the second power lead 32 are spaced apart from each other. The second power lead 32 is spaced apart from the conductive substrate 22A. Each of the first power lead 31 and the second power lead 32 is an example of the “conductive member”, and the material of each of the first power lead 31 and the second power lead 32 is an example of the “first material”.

As shown in FIG. 4, the first power lead 31 includes a pad portion 311 and a terminal portion 312.

The pad portion 311 is the portion of the first power lead 31 that is covered with the sealing resin 70. The pad portion 311 is electrically connected to the conductive substrate 22A via the first spacer 26A. As shown in FIGS. 2, 4, and 10, the pad portion 311 is electrically bonded to the first spacer 26A. The method for the electrical bonding is not particularly limited, and may be laser bonding, or bonding with a conductive bonding member, for example.

The terminal portion 312 is the portion of the first power lead 31 that is exposed from the sealing resin 70. As shown in FIGS. 3, 4, 6, 7 and 10, the terminal portion 312 extends from the sealing resin 70 in the x1 direction.

As shown in FIG. 4, the second power lead 32 includes a pad portion 321 and a terminal portion 322.

The pad portion 321 is the portion of the second power lead 32 that is covered with the sealing resin 70. The pad portion 321 includes a joining portion 321a, a plurality of extending portions 321b, and a connecting portion 321c.

The joining portion 321a has a band shape extending in the y direction. The joining portion 321a connects the extending portions 321b.

Each of the extending portions 321b has a band shape extending from the joining portion 321a in the x2 direction. In the present embodiment, each of the extending portions 321b extends from the joining portion 321a in the x direction to overlap with a second semiconductor element 10B in plan view. The extending portions 321b extend across the conductive substrate 22A and the conductive substrate 22B in plan view. The tip of each of the extending portions 321b overlaps with a second block 62 in plan view. In plan view, the extending portions 321b are aligned and spaced apart from each other in the y direction. The extending portions 321b are electrically connected to the source electrodes 111 (source electrodes) of the respective second semiconductor elements 10B via the conductive blocks 60. As shown in FIGS. 4 and 10, the tip of each of the extending portions 321b is electrically bonded to a second block 62. The method for the electrical bonding is not particularly limited, and may be laser bonding, or bonding with a conductive bonding member, for example.

The connecting portion 321c connects the joining portion 321a and the terminal portion 322. In the present embodiment, the connecting portion 321c extends in the x1 direction from an edge of the joining portion 321a, specifically from a portion of the edge that is offset in the y2 direction and in the x1 direction in plan view, as shown in FIG. 4.

The terminal portion 322 is the portion of the second power lead 32 that is exposed from the sealing resin 70. As shown in FIGS. 1, 3, 4, and 7, the terminal portion 322 extends from the sealing resin 70 in the x1 direction. The terminal portion 322 has a rectangular shape in plan view. As shown in FIGS. 3, 4, and 7, the terminal portion 322 is offset in the y2 direction relative to the terminal portion 312 of the first power lead 31 in plan view. In the present embodiment, the terminal portion 322 has the same shape as the terminal portion 312, but the present disclosure is not limited to this.

The third power lead 33 is a metal plate. The metal plate is made of Cu or a Cu alloy. The material of the third power lead 33 is not limited to Cu or a Cu alloy, and may be aluminum, for example. As shown in FIGS. 1 to 4, 6, 7, and 10, the third power lead 33 is offset in the x2 direction in the semiconductor device A1. The third power lead 33 outputs AC power (voltage) converted by the semiconductor elements 10.

As shown in FIGS. 4 and 10, the third power lead 33 includes a pad portion 331 and a terminal portion 332.

The pad portion 331 is the portion of the third power lead 33 that is covered with the sealing resin 70. The pad portion 331 is electrically connected to the conductive substrate 22B via the second spacer 26B. As shown in FIGS. 2, 4, and 10, the pad portion 331 is electrically bonded to the second spacer 26B. The method for the electrical bonding is not particularly limited, and may be laser bonding, or bonding with a conductive bonding member, for example.

The terminal portion 332 is the portion of the third power lead 33 that is exposed from the sealing resin 70. As shown in FIGS. 3, 4, 6, 7 and 10, the terminal portion 332 extends from the sealing resin 70 in the x2 direction.

As shown in FIGS. 1 to 7, the pair of gate leads 34A and 34B are positioned adjacent to the conductive substrates 22A and 22B in the y direction. A gate voltage for driving the first semiconductor elements 10A is applied to the gate lead 34A. A gate voltage for driving the second semiconductor elements 10B is applied to the gate lead 34B.

As shown in FIG. 5, the pair of gate leads 34A and 34B each include a pad portion 341 and a terminal portion 342. The pad portion 341 of each of the gate leads 34A and 34B is covered with the sealing resin 70. The gate leads 34A and 34B are supported by the sealing resin 70. Each of the terminal portions 342 is connected to the corresponding pad portion 341 and exposed from the sealing resin 70. Each of the terminal portions 342 has an L-shape as viewed in the x direction. In the present embodiment, each of the terminal portions 342 protrudes from the surface of the sealing resin 70 that faces in the y1 direction (resin side surface 733).

As shown in FIGS. 1 to 7, the pair of driver source leads 35A and 35B are positioned adjacent to the pair of gate leads 34A and 34B in the x direction. The driver source lead 35A provides a reference potential for the gate voltage for driving the first semiconductor elements 10A. The driver source lead 35B provides a reference potential for the gate voltage for driving the second semiconductor elements 10B.

As shown in FIG. 5, the pair of driver source leads 35A and 35B each include a pad portion 351 and a terminal portion 352. The pad portion 351 of each of the driver source leads 35A and 35B is covered with the sealing resin 70. The driver source leads 35A and 35B are supported by the sealing resin 70. Each of the terminal portions 352 is connected to the corresponding pad portion 351 and exposed from the sealing resin 70. Each of the terminal portions 352 has an L-shape as viewed in the x direction. In the present embodiment, each of the terminal portions 352 protrudes from the surface of the sealing resin 70 that faces in the y1 direction (resin side surface 733).

As shown in FIGS. 1 to 7, each of the dummy leads 36 is positioned opposite the driver source lead 35A or 35B with respect to the gate lead 34A or 34B in the x direction. In the present embodiment, the number of dummy leads 36 is four. Two of the four dummy leads 36 are offset in one sense of the x direction (i.e., x2 direction). The other two of the four dummy leads 36 are offset in the other sense of the x direction (i.e., x1 direction). Each of the dummy leads 36 is not limited to the configuration described above. It is possible to omit the dummy leads 36.

As shown in FIG. 5, each of the dummy leads 36 includes a pad portion 361 and a terminal portion 362. The pad portion 361 of each of the dummy leads 36 is covered with the sealing resin 70. The dummy leads 36 are supported by the sealing resin 70. Each of the terminal portions 362 is connected to the corresponding pad portion 361 and exposed from the sealing resin 70. Each of the terminal portions 362 has an L-shape as viewed in the x direction. In the present embodiment, each of the terminal portions 362 protrudes from the surface of the sealing resin 70 that faces in the y1 direction (resin side surface 733).

In the present embodiment, the gate leads 34A and 34B, the driver source leads 35A and 35B, and the dummy leads 36 have substantially the same shape. As shown in FIGS. 1 to 7, these leads are aligned along the x direction. In the semiconductor device A1, the leads (the first power lead 31, the second power lead 32, the third power lead 33, the pair of gate leads 34A and 34B, the pair of driver source leads 35A and 35B, and the dummy leads 36) are formed from the same lead frame.

The intermediate leads 40 connect the first semiconductor elements 10A and the conductive substrate 22B. The intermediate leads 40 are made of Cu or a Cu alloy, for example. The material of the intermediate leads 40 is not limited to Cu or a Cu alloy, and may be a clad material such as CIC, or aluminum. Each of the intermediate leads 40 is a connecting member having a flat plate-like shape. As shown in FIG. 4, each of the intermediate leads 40 has a rectangular shape extending in the x direction in plan view. The intermediate leads 40 overlap with the extending portions 321b of the second power lead 32 in plan view. Each of the intermediate leads 40 is an example of the “conductive member”, and the material of each of the intermediate leads 40 is an example of the first material”.

As shown in FIG. 10, each of the intermediate leads 40 includes a first bonding portion 41, a second bonding portion 42, and a communicating portion 43.

As shown in FIG. 10, the first bonding portion 41 is a portion bonded to the first block 61. In the present embodiment, the first bonding portion 41 and the first block 61 are electrically bonded to each other. The method for the electrical bonding is not particularly limited, and may be laser bonding, or bonding with a conductive bonding member, for example.

As shown in FIG. 10, the second bonding portion 42 is a portion bonded to the conductive substrate 22B. In the present embodiment, the second bonding portion 42 and the conductive substrate 22B are electrically bonded to each other. The method for the electrical bonding is not particularly limited, and may be laser bonding, or bonding with a conductive bonding member, for example.

The communicating portion 43 is connected to the first bonding portion 41 and the second bonding portion 42. The communicating portion 43 has the same dimension in the z direction as each of the first bonding portion 41 and the second bonding portion 42. In the present embodiment, the communicating portion 43 is partially bent in the z direction. With this bent portion, the communicating portion 43 can connect the first bonding portion 41 and the second bonding portion 42 that are located at different positions in the z direction.

The wire members 50 are wires (bonding wires). The wire members 50 are electrically conductive, and may be made of aluminum, gold, or Cu. As shown in FIGS. 4 and 5, the wire members 50 in the present embodiment include a plurality of gate wires 51, a plurality of driver source wires 52, a pair of first connecting wires 53, and a pair of second connecting wires.

As shown in FIG. 5, each of the gate wires 51 has one end (first end) bonded to the gate electrode 112 of a semiconductor element 10 and the other end (second end) bonded to either one of the gate layers 24A and 24B. The gate wires 51 include those electrically connecting the gate electrodes 112 of the first semiconductor elements 10A and the gate layer 24A, and those electrically connecting the gate electrodes 112 of the second semiconductor elements 10B and the gate layer 24B.

As shown in FIG. 5, each of the driver source wires 52 has one end bonded to the driver source electrode 113 of a semiconductor element 10 and the other end bonded to either one of the driver source layers 25A and 25B. The driver source wires 52 include those electrically connecting the driver source electrodes 113 of the first semiconductor elements 10A and the driver source layer 25A, and those electrically connecting the driver source electrodes 113 of the second semiconductor elements 10B and the driver source layer 25B.

As shown in FIG. 5, one of the pair of first connecting wires 53 connects the gate layer 24A and the gate lead 34A, and the other connects the gate layer 24B and the gate lead 34B. One of the first connecting wires 53 has one end bonded to the gate layer 24A and the other end bonded to the pad portion 341 of the gate lead 34A. The other one of the first connecting wires 53 has one end bonded to the gate layer 24B and the other end bonded to the pad portion 341 of the gate lead 34B.

As shown in FIG. 5, one of the pair of second connecting wires connects the driver source layer 25A and the driver source lead 35A, and the other connects the driver source layer 25B and the driver source lead 35B. One of the second connecting wires has one end bonded to the driver source layer 25A and the other end bonded to the pad portion 351 of the driver source lead 35A. The other one of the second connecting wires 54 has one end bonded to the driver source layer 25B and the other end bonded to the pad portion 351 of the driver source lead 35B.

The conductive blocks 60 are electrically conductive. The conductive blocks 60 are bonded to the respective semiconductor elements 10. Each of the conductive blocks 60 has a dimension of about 0.1 to 2.0 mm in the z direction, but the present disclosure is not limited to this. The conductive blocks 60 include the first blocks 61 and the second blocks 62.

The first blocks 61 are bonded to the respective first semiconductor elements 10A. The first blocks 61 are electrically bonded to the first semiconductor elements 10A by solder, for example. The first blocks 61 face the element obverse surfaces 101 of the respective first semiconductor elements 10A. As shown in FIG. 4, each of the first blocks 61 in the present embodiment is in the form of a columnar body and has a rectangular shape in plan view. The shape of each of the first blocks 61 in plan view is not limited to this, and may be circular, elliptical, or polygonal. The first blocks 61 are made of Cu or a Cu alloy, for example.

The second blocks 62 are bonded to the respective second semiconductor elements 10B. The second blocks 62 are electrically bonded to the second semiconductor elements 10B by solder, for example. The second blocks 62 face the element obverse surfaces 101 of the respective second semiconductor elements 10B. In the present embodiment, each of the second blocks 62 has a dimension of about 1.83 mm in the z direction, for example. However, the present disclosure is not limited to this. As shown in FIGS. 4 and 10, each of the second blocks 62 in the present embodiment is in the form of a columnar body and has a rectangular shape in plan view. The shape of each of the second blocks 62 in plan view is not limited to this, and may be circular, elliptical, or polygonal. The second blocks 62 are made of Cu or a Cu alloy, for example.

The dimension of each first block 61 in the z direction is smaller than the dimension of each second block 62 in the z direction. In the present embodiment, the dimension of each second block 62 in the z direction is about 1.83 mm as described above. Accordingly, the dimension of each first block 61 in the z direction is smaller than this value. In this way, the extending portions 321b of the second power lead 32 can be arranged above the intermediate leads 40.

The capacitor 81 is a chip-type capacitor having a first end and a second end, where the first end is placed on the pad portion 311 of the first power lead 31 and the second end is placed on the joining portion 321a of the second power lead 32. Bonding between the capacitor 81 and each of the power leads 31 and 32 may be achieved with a conductive bonding member, for example. Electrically connecting the capacitor 81 to the first power lead 31 and the second power lead 32 can stabilize the source voltage (input voltage) applied across the first power lead 31 and the second power lead 32. The capacitor 81 may also be referred to as a DC-link capacitor. Unlike the present embodiment, it is possible to omit the capacitor 81.

As shown in FIGS. 4 and 10, the sealing resin 70 covers the semiconductor elements 10, a portion of the support substrate 20, portions of the leads (the first power lead 31, the second power lead 32, the third power lead 33, the pair of gate leads 34A and 34B, the pair of driver source leads 35A and 35B, and the dummy leads 36), the intermediate leads 40, the wire members 50, and the conductive blocks 60. The sealing resin 70 is made of epoxy resin, for example. As shown in FIGS. 1, 3, and FIGS. 6 to 10, the sealing resin 70 has a resin obverse surface 71, a resin reverse surface 72, and a plurality of resin side surfaces 731 to 734.

As shown in FIG. 6, and FIGS. 8 to 10, the resin obverse surface 71 and the resin reverse surface 72 are spaced apart and face away from each other in the z direction. The resin obverse surface 71 faces in the z2 direction, and the resin reverse surface 72 faces in the z1 direction. As shown in FIG. 7, the resin reverse surface 72 has a frame shape surrounding the reverse surface 212A of the insulating substrate 21A and the reverse surface 212B of the insulating substrate 21B in plan view. The reverse surfaces 212A and 212B are exposed from the resin reverse surface 72. As shown in FIG. 3, and FIGS. 6 to 10, each of the resin side surfaces 731 to 734 is connected to the resin obverse surface 71 and the resin reverse surface 72 and sandwiched between them in the z direction. In the present embodiment, the resin side surfaces 731 and 732 are spaced apart and face away from each other in the x direction. The resin side surface 731 faces in the x1 direction, and the resin side surface 732 faces in the x2 direction. The resin side surfaces 733 and 734 are spaced apart and face away from each other in the y direction. The resin side surface 733 faces in the y1 direction, and the resin side surface 734 faces in the y2 direction.

The covering layer 90 covers at least a portion of the “conductive member”, and is made of a second material. The second material satisfies at least one of the following three requirements: (1) having a magnetic permeability higher than the first material of the “conductive member”; (2) having an electrical resistivity higher than the first material; and (3) having a dielectric loss tangent larger than zero (larger than the dielectric loss tangent of an ideal dielectric material). In these respects, it is assumed that the first material is Cu, for example. In this case, the second material having a magnetic permeability higher than the first material may be a magnetic metal such as Ni, Co, or Fe. The second material having an electrical resistivity higher than the first material may be a metal such as Ni, W, or Mo, a conductive polymer, or a transparent conductive film. The second material having a dielectric loss tangent larger than zero may be a dielectric material. When the magnetic permeability of the second material is set higher than the magnetic permeability of the first material, the relative magnetic permeability of the second material is preferably not less than 10, for example. When the electrical resistivity of the second material is set higher than the electrical resistivity of the first material, the electrical resistivity of the second material is preferably not less than twice the electrical resistivity of the first material, for example. Concerning the requirement (3) above, the dielectric loss tangent of the second material is preferably not less than 0.01. The thickness of the covering layer 90 is not particularly limited, and may be 1 μm to 5 μm, for example. When the covering layer 90 is made of metal, the covering layer 90 can be formed by plating such as magnetic plating.

The second material constituting the covering layer 90 may be a magnetic metal that has a magnetic permeability higher than the first material and also an electrical resistivity higher than the first material. The covering layer 90 may be configured such that the magnetic permeability of the second material is higher than the magnetic permeability of the first material, and that the dielectric loss tangent of the second material is larger than zero. The covering layer 90 may be configured such that the electrical resistivity of the second material is higher than the electrical resistivity of the first material, and that the dielectric loss tangent of the second material is larger than zero. The covering layer 90 may be configured such that the magnetic permeability of the second material is higher than the magnetic permeability of the first material, that the electrical resistivity of the second material is higher than the electrical resistivity of the first material, and that the dielectric loss tangent of the second material is larger than zero.

As shown in FIGS. 1 to 11, the covering layer 90 in the present embodiment has a first portion 91 and a second portion 92. The first portion 91 covers at least a portion of the first power lead 31. In the present embodiment, the first portion 91 covers the entirety of the first power lead 31. As shown in FIG. 11, when the first power lead 31 functions as the path of the main circuit current, the entire periphery of the cross section of the first power lead 31 is covered with the first portion 91. The second portion 92 covers at least a portion of the second power lead 32. In the present embodiment, the second portion 92 covers the entirety of the second power lead 32. As with the first portion 91, when the second power lead 32 functions as the path of the main circuit current, the entire periphery of the cross section of the second power lead 32 is covered with the second portion 92.

Next, the advantages of the semiconductor device A1 will be described.

In general, when an alternating current flows through a conductor, the current density increases toward the surface of the conductor (which is referred to as skin effect). The skin effect becomes more prominent as the frequency of the alternating current increases. In the present embodiment, the covering layer 90 is provided for the conductive member that forms the path of the main circuit current in the semiconductor device A1. More specifically, the covering layer 90 is provided at a portion having a high alternating current density due to the skin effect. When the magnetic permeability of the second material constituting the covering layer 90 is higher than the magnetic permeability of the first material (e.g., Cu) constituting the conductive member (e.g., the first power lead 31 and the second power lead 32), the skin effect becomes more prominent, thus causing an increase in the alternating-current resistance of the current path. This makes it possible to attenuate the alternating current flowing through the covering layer 90 and suppress ringing. On the other hand, skin effect is relatively unlikely to occur in the low-frequency component of the current. Accordingly, the low-frequency component of the current is not unduly attenuated by the covering layer 90. Since ringing can be suppressed, it is possible to simplify the snubber circuit in the semiconductor device A1 and improve the reliability of the semiconductor device A1 per se.

Even when the electrical resistivity of the second material constituting the covering layer 90 is higher than the electrical resistivity of the first material (e.g., Cu) constituting the conductive member (e.g., the first power lead 31 and the second power lead 32), it is possible to attenuate the alternating current flowing through the covering layer 90 and suppress ringing. As described above, the low-frequency component of the current is not unduly attenuated by the covering layer 90.

Furthermore, even when the dielectric loss tangent of the second material constituting the covering layer 90 is larger than zero (larger than the dielectric loss tangent of an ideal dielectric material), it is possible to consume the energy of the alternating current flowing through the covering layer 90 as dielectric loss and suppress ringing.

The above-described advantages of the second material, which are obtained by the requirements relating to the magnetic permeability, the electrical resistivity, and the dielectric loss tangent, can be achieved independently of each other. Accordingly, while ringing can be suppressed effectively when only one of the requirements relating to the magnetic permeability, electrical resistivity, and dielectric loss tangent of the second material is satisfied, it can be suppressed more effectively when two of the requirements are satisfied, and even more so when all of the three requirements are satisfied.

FIGS. 12 to 21 show variations and other embodiments according to the present disclosure. In these figures, elements identical or similar to those in the above embodiment are provided with the same reference signs.

FIG. 12 shows a first variation of the semiconductor device A1. In a semiconductor device A11 of the present variation, the configuration of the covering layer 90 is different from the above example. According to the present variation, the first portion 91, which is a portion of the covering layer 90, covers only a portion of the periphery, rather than the entire periphery, of the cross section of the first power lead 31 through which the main circuit current flows. More specifically, the first portion 91 covers only three sides (top side and two lateral sides) of the rectangular cross section of the first power lead 31, and does not cover the remaining side (bottom side) thereof (i.e., the bottom side is exposed from the first portion 91). The three sides (the top side and the two lateral sides) are fully covered with the first portion 91.

FIG. 13 shows a second variation of the semiconductor device A1. According to a semiconductor device A12 of the present variation, the first portion 91, which is a portion of the covering layer 90, covers the entire periphery of the cross section of the first power lead 31 through which the main circuit current flows, with each of the sides (the top side, the two lateral sides, and the bottom side) partially exposed from the first portion 91 (i.e., with each of the sides partially covered by the first portion 91). In the illustrated example, the first portion 91 has a plurality of gaps arranged at intervals along the entire periphery of the rectangular cross section. The gaps include one or more gaps at each side of the cross section. The first portion 91 (covering layer 90) having such a configuration may be formed with a plurality of small holes or slits. Alternatively, the first portion 91 (covering layer 90) may be a group of small regions that are spaced apart from each other.

The semiconductor devices A11 and A12 can also suppress ringing. As can be understood from these variations, the covering layer 90 is not limited to a specific configuration. Even when the covering layer 90 covers a portion of the conductive member (see FIGS. 12 and 13), ringing can be suppressed depending on the position and size of the region formed with the covering layer 90.

FIGS. 14 to 16 show a semiconductor device according to a second embodiment of the present disclosure. In a semiconductor device A2 of the present embodiment, the covering layer 90 has a configuration different from the covering layer 90 of the semiconductor device A1.

In the second embodiment, the first portion 91 covers a portion of the first power lead 31, and the second portion 92 covers a portion of the second power lead 32. More specifically, the first portion 91 does not cover the portion of the first power lead 31 that forms the path between the first semiconductor elements 10A and the capacitor 81. In other words, the first portion 91 covers the terminal portion 312 of the first power lead 31, but does not cover the pad portion 311.

The second portion 92 does not cover the portion of the second power lead 32 that forms the path between the second semiconductor elements 10B and the capacitor 81. In other words, the second portion 92 covers the terminal portion 322 of the second power lead 32 and the connecting portion 321c of the pad portion 321, but does not cover the joining portion 321a or the extending portions 321b.

The second embodiment can also suppress ringing. The portions of the first power lead 31 and the second power lead 32 that constitute the path in which only the charge/discharge current of the capacitor 81 flows have a resistance equivalent to the ESR of the capacitor 81. In other words, since the path is where an abrupt charge/discharge current flows to the capacitor 81, it is not preferable for the AC resistance to be too high. In this regard, the configuration described above where the first portion 91 and the second portion 92 do not cover the portions of the first power lead 31 and the second power lead 32 is preferable to perform abrupt charge and discharge to the capacitor 81.

FIGS. 17 to 19 show a semiconductor device according to a third embodiment of the present disclosure. In a semiconductor device A3 of the present embodiment, the covering layer 90 has a configuration different from the covering layers 90 of the semiconductor devices A1 and A2.

In the third embodiment, the covering layer 90 includes a first portion 91, a second portion 92, a third portion 93, a fourth portion 94, a fifth portion 95, and a sixth portion 96. The first portion 91 and the second portion 92 have the same configurations as the first portion 91 and the second portion 92 in the semiconductor device A1.

The third portion 93 covers the first metal layer, namely one of the copper films 220n of the conductive substrate 22A. The fourth portion 94 covers the first spacer 26A. The fifth portion 95 covers the second metal layer, namely one of the copper films 220n of the conductive substrate 22B. The sixth portion 96 covers the intermediate leads 40. In the illustrated example, the third portion 93 covers every surface of the copper film 220n except the surface to which the graphite substrate 220m is bonded. The fifth portion 95 covers every surface of the copper film 220n except the surface to which the graphite substrate 220m is bonded.

The third embodiment can also suppress ringing. As can be understood from the present embodiment, the areas where the covering layer 90 is provided can be changed appropriately depending on a desired degree of ringing suppression and the configuration of the semiconductor device.

FIGS. 20 and 21 show a semiconductor device according to a fourth embodiment of the present disclosure. In a semiconductor device A4 of the present embodiment, the configuration of the first power lead 31 and the second power lead 32 is different from the examples in the above embodiments.

In the fourth embodiment, the terminal portion 312 of the first power lead 31 and the terminal portion 322 of the second power lead 32 overlap with each other as viewed in the z direction. The terminal portion 312 is covered with the first portion 91, and the terminal portion 322 is covered with the second portion 92. An insulator 89 is provided between the terminal portion 312 and the terminal portion 322. The insulator 89 is provided to insulate the terminal portion 312 and the terminal portion 322 from each other when an expected voltage is applied across the terminal portion 312 and the terminal portion 322.

In the fourth embodiment, the second material of the covering layer 90 has at least a dielectric loss tangent larger than 0 (larger than the dielectric loss tangent of an ideal dielectric material), such as a dielectric loss tangent of not less than 0.01. When the covering layer 90 having such a configuration is employed, the terminal portion 312 and the terminal portion 322, together with the covering layer 90 and the insulator 89 provided therebetween, form a portion having a capacitance, namely a portion having an electrical configuration similar to a capacitor.

The fourth embodiment can also suppress ringing. The capacitance formed by the terminal portion 312, the terminal portion 322, and the covering layer 90 and the insulator 89 that are provided therebetween is expected to achieve a synergistic effect with the capacitor 81, and can enhance the effect of stabilizing the source voltage (input voltage) applied across the first power lead 31 and the second power lead 32.

The semiconductor device according to the present disclosure is not limited to the above embodiments and variations. Various design changes can be made to the specific configurations of the elements of the semiconductor device according to the present disclosure.

A semiconductor device according to the present disclosure includes embodiments described in the following clauses.

Clause 1.

A semiconductor device comprising:

at least one semiconductor element having a switching function;

a conductive member that forms a path of a current switched by the semiconductor element, and that is made of a first material; and

a covering layer that covers at least a portion of the conductive member, and that is made of a second material,

wherein the second material satisfies at least one of the following three requirements:

(a) having a magnetic permeability higher than the first material;

(b) having an electrical resistivity higher than the first material; and

(c) having a dielectric loss tangent larger than zero.

Clause 2.

The semiconductor device according to clause 1, wherein the second material is a magnetic conductor having a magnetic permeability higher than the first material and having an electrical resistivity higher than the first material.

Clause 3.

The semiconductor device according to clause 2, wherein the second material has a dielectric loss tangent larger than zero.

Clause 4.

The semiconductor device according to clause 1, wherein the second material has a magnetic permeability higher than the first material, and has a dielectric loss tangent larger than zero.

Clause 5.

The semiconductor device according to clause 1, wherein the second material has an electrical resistivity higher than the first material, and has a dielectric loss tangent larger than zero.

Clause 6.

The semiconductor device according to any of clauses 1 to 5, wherein the covering layer has a thickness of 1 μm to 5 μm.

Clause 7.

The semiconductor device according to any of clauses 1 to 6, wherein a relative magnetic permeability of the second material is not less than 10.

Clause 8.

The semiconductor device according to any of clauses 1 to 7, wherein the electrical resistivity of the second material is not less than twice the electrical resistivity of the first material.

Clause 9.

The semiconductor device according to any of clauses 1 to 8, wherein the dielectric loss tangent of the second material is not less than 0.01.

Clause 10.

The semiconductor device according to any of clauses 1 to 9, further comprising a capacitor having a first end and a second end for electrical connection,

wherein the at least one semiconductor element includes a plurality of semiconductor elements that form a half-bridge including at least a pair of upper arm and lower arm,

the plurality of semiconductor elements include a first semiconductor element in the upper arm and a second semiconductor element in the lower arm,

the conductive member includes a first metal layer connected to a drain electrode of the first semiconductor element, a first power lead connected to the first metal layer, and a second power lead connected to a source electrode of the second semiconductor element,

the first end of the capacitor is connected to the first power lead, and the second end of the capacitor is connected to the second power lead, and

the covering layer includes a first portion covering the first power lead and a second portion covering the second power lead.

Clause 11.

The semiconductor device according to clause 10, wherein the first power lead includes a portion forming a path between the first semiconductor element and the capacitor, and the portion of the first power lead is not covered with the first portion.

Clause 12.

The semiconductor device according to clause 10 or 11, wherein the second power lead includes a portion forming a path between the second semiconductor element and the capacitor, and the portion of the second power lead is not covered with the second portion.

Clause 13.

The semiconductor device according to any of clauses 10 to 12, wherein the covering layer includes a third portion covering the first metal layer.

Clause 14.

The semiconductor device according to any of clauses 10 to 13, wherein the conductive member includes a second metal layer connected to a drain electrode of the second semiconductor element, and a third power lead connected to the second metal layer, and

the second metal layer and the third power lead are not covered with the covering layer.

Clause 15.

The semiconductor device according to clause 14, wherein the conductive member includes an intermediate lead connected to a source electrode of the first semiconductor element and the second metal layer, and the intermediate lead is not covered with the covering layer.

Clause 16.

The semiconductor device according to any of clauses 10 to 15, wherein the conductive member includes a first spacer interposed between the first metal layer and the first power lead, and

the covering layer includes a fourth portion covering the first spacer.

Clause 17.

The semiconductor device according to any of clauses 10 to 16, wherein the conductive member includes a conductor interposed between the source electrode of the second semiconductor element and the second power lead.

Clause 18.

The semiconductor device according to any of clauses 1 to 17, wherein the semiconductor element is one of a SiC MOSET, a SiC IGBT, a Si MOSFET, a Si IGBT, and a GaN HEMT.

### REFERENCE SIGNS

A1, A11, A12, A2, A3, A4: Semiconductor device
10: Semiconductor element
10A: First semiconductor element
10B: Second semiconductor element
11: Obverse surface electrode
12: Drain electrode (Reverse surface electrode)
13: Insulating film
20: Support substrate
21, 21A, 21B: Insulating substrate
22A, 22B: Conductive substrate
23A, 23B: Insulating layer 23A
24A, 24B: Gate layer
25A, 25B: Driver source layer
26A: First spacer
31: First power lead
32: Second power lead
33: Third power lead
34A, 34B: Gate lead
35A, 35B: Driver source lead
36: Dummy lead
40: Intermediate lead
41: First bonding portion
42: Second bonding portion
43: Communicating portion
50: Wire member
51: Gate wire
52: Driver source wire
53: First connecting wire
54: Second connecting wire
60: Conductive block
61: First block
62: Second block
70: Sealing resin
71: Resin obverse surface
72: Resin reverse surface
81: Capacitor
89: Insulator
90: Covering layer
91: First portion
92: Second portion
93: Third portion
94: Fourth portion
95: Fifth portion
96: Sixth portion
101: Element obverse surface
102: Element reverse surface
111: Source electrode
112: Gate electrode
113: Driver source electrode
211A, 211B: Obverse surface
212A, 212B: Reverse surface
220A, 220B: Substrate bonding member
220m: Graphite substrate
220n: Copper film
221A, 221B: Obverse surface
222A, 222B: Reverse surface
260A: Spacer bonding member
260B: Spacer bonding member
311, 321, 331, 341, 351, 361: Pad portion
312, 322, 332, 342, 352, 362: Terminal portion
321a: Joining portion
321b: Extending portion
321c: Connecting portion
731, 732, 733, 734: Resin side surface

1. A semiconductor device comprising:
at least one semiconductor element having a switching function;
a conductive member that forms a path of a current switched by the semiconductor element, and that is made of a first material; and
a covering layer that covers at least a portion of the conductive member, and that is made of a second material,
wherein the second material satisfies at least one of the following three requirements:
(a) having a magnetic permeability higher than the first material;
(b) having an electrical resistivity higher than the first material; and
(c) having a dielectric loss tangent larger than zero.

2. The semiconductor device according to claim 1, wherein the second material is a magnetic conductor having a magnetic permeability higher than the first material and having an electrical resistivity higher than the first material.

3. The semiconductor device according to claim 2, wherein the second material has a dielectric loss tangent larger than zero.

4. The semiconductor device according to claim 1, wherein the second material has a magnetic permeability higher than the first material, and has a dielectric loss tangent larger than zero.

5. The semiconductor device according to claim 1, wherein the second material has an electrical resistivity higher than the first material, and has a dielectric loss tangent larger than zero.

6. The semiconductor device according to claim 1, wherein the covering layer has a thickness of 1 μm to 5 μm.

7. The semiconductor device according to claim 1, wherein a relative magnetic permeability of the second material is not less than 10.

8. The semiconductor device according to claim 1, wherein the electrical resistivity of the second material is not less than twice the electrical resistivity of the first material.

9. The semiconductor device according to claim 1, wherein the dielectric loss tangent of the second material is not less than 0.01.

10. The semiconductor device according to claim 1, further comprising a capacitor having a first end and a second end for electrical connection,
wherein the at least one semiconductor element includes a plurality of semiconductor elements that form a half-bridge including at least a pair of upper arm and lower arm,
the plurality of semiconductor elements include a first semiconductor element in the upper arm and a second semiconductor element in the lower arm,
the conductive member includes a first metal layer connected to a drain electrode of the first semiconductor element, a first power lead connected to the first metal layer, and a second power lead connected to a source electrode of the second semiconductor element,
the first end of the capacitor is connected to the first power lead, and the second end of the capacitor is connected to the second power lead, and
the covering layer includes a first portion covering the first power lead and a second portion covering the second power lead.

11. The semiconductor device according to claim 10, wherein the first power lead includes a portion forming a path between the first semiconductor element and the capacitor, and the portion of the first power lead is not covered with the first portion.

12. The semiconductor device according to claim 10, wherein the second power lead includes a portion forming a path between the second semiconductor element and the capacitor, and the portion of the second power lead is not covered with the second portion.

13. The semiconductor device according to claim 10, wherein the covering layer includes a third portion covering the first metal layer.

14. The semiconductor device according to claim 10, wherein the conductive member includes a second metal layer connected to a drain electrode of the second semiconductor element, and a third power lead connected to the second metal layer, and
the second metal layer and the third power lead are not covered with the covering layer.

15. The semiconductor device according to claim 14, wherein the conductive member includes an intermediate lead connected to a source electrode of the first semiconductor element and the second metal layer, and the intermediate lead is not covered with the covering layer.

16. The semiconductor device according to claim 10, wherein the conductive member includes a first spacer interposed between the first metal layer and the first power lead, and
the covering layer includes a fourth portion covering the first spacer.

17. The semiconductor device according to claim 10, wherein the conductive member includes a conductor interposed between the source electrode of the second semiconductor element and the second power lead.

18. The semiconductor device according to claim 1, wherein the semiconductor element is one of a SiC MOSET, a SiC IGBT, a Si MOSFET, a Si IGBT, and a GaN HEMT.
